(19) United States
(12) Patent Application Publication
(10) Pub. No.: US 2024/0128103 A1
(43) Pub. Date: Apr. 18, 2024

(54) WAFER TRANSPORT SYSTEM AND TRANSPORTING METHOD USING THE SAME

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Qun DENG, Nanchang City (CN); Guang YANG, Shanghai City (CN); Qinhong ZHANG, Shanghai City (CN); Zihao CAO, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/194,369

(22) Filed: Mar. 31, 2023

(30) Foreign Application Priority Data
Oct. 12, 2022 (CN) 202222685519.0

(51) Int. Cl. H01L 21/67; H01L 21/677

(52) U.S. Cl. CPC H01L 21/67259; H01L 21/67742; H01L 21/67745

(57) ABSTRACT

A method includes receiving, by a control module of a wafer transport system, an indication of wafer transporting; calculating, by the control module, a route for transporting a first wafer carrier according to the indication; moving, by a control unit of a wafer transport device of the wafer transport system, the wafer transport device to a first stocker storing the first wafer carrier along the route; performing, by the control unit, a safety monitoring process during a movement of the wafer transport device; stopping, by the control unit, the wafer transport device in front of the first stocker; and identifying, by an identification device of the wafer transport device, the first wafer carrier loaded on a rack of the wafer transport device.

### PRIORITY CLAIM AND CROSS-REFERENCE

The present application claims priority to China Application Serial Number 202222685519.0, filed Oct. 12, 2022, which is herein incorporated by reference.

### BACKGROUND

The manufacture of semiconductor devices involves the performance of a series of process operations using a variety of high-tech production and metrology tools in a certain order and often within a certain period of time. The primary function of a wafer logistics system in a wafer fabrication facility, or “fab,” is to deliver the wafers to each of the tools at the right time. The fabrication process often results in the need for cross-floor and cross-phase transportation within a single fab and/or cross-fab transportation between fabs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an illustrative diagram of a wafer fabrication facility in accordance with some embodiments.

FIGS. 2A and 2B are perspective views of a wafer transport device of FIG. 1 in accordance with some embodiments.

FIG. 3 is a side view of a pair of optical detectors in FIG. 2A.

FIG. 4 is an enlarged cross-sectional view of the wafer transport device and a wafer carrier in FIG. 2A.

FIG. 5 is a front view of a stocker in FIG. 1 in accordance with some embodiments.

FIG. 6 is a front view of the wafer transport device in FIG. 2A.

FIG. 7 is a perspective view of the wafer transport device of FIG. 2A during movement.

FIG. 8 is a front view of a body portion and a connecting portion in FIG. 2A.

FIG. 9 is a flowchart illustrating a method for transporting wafers (in the wafer carriers) in accordance with some embodiments of the present disclosure.

FIG. 10 is a flowchart illustrating a method for maintaining the wafer transport device in accordance with some embodiments of the present disclosure.

FIG. 11A is an enlarged view of area Pin FIG. 8.

FIG. 11B is an enlarged view of area P in FIG. 8 when a steering wheel is lifted up.

FIGS. 12A and 12B are enlarged side views of a first side panel (or a second side panel) in accordance with some embodiments.

FIG. 13 is an illustrative diagram of a wafer fabrication facility in accordance with some embodiments.

FIG. 14 is a schematic diagram illustrating a computer system in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

In a semiconductor fabrication facility (FAB), wafers are frequently transported between various processing tools in corresponding bays, so as to carry out different semiconductor manufacturing processes. In modern semiconductor fabrication facilities with a low-level-of-cleanliness (e.g., Class 100) cleanroom, overhead shuttle (OHS) systems and overhead hoist transport (OHT) systems are extensively used to automate the wafer transport process. The OHS/OHT systems grip wafer carriers to transfer wafers to different locations. The wafer carriers used in the OHS/OHT systems have sealing configurations, i.e., the environment in the wafer carrier is isolated/independent from the environment outside the wafer carrier when the wafer carrier is sealed or closed. Otherwise, particles dropped from the OHS/OHT systems may contaminate the wafers in the wafer carriers.

A FAB using open cassettes, each of which has an interior environment communicated with an environment of the FAB when the open cassette is closed, as wafer carriers can be a high-level-of-cleanliness (e.g., Class 1) cleanroom to exclude contamination particles in the FAB. The OHS/OHT system may be not suitable for the cleanroom because the OHS/OHT system may be a source of the contamination particles. As such, some embodiments in the present disclosure provide wafer transport systems and transporting methods thereof to be used in a high-level-of-cleanliness cleanroom to transport the open cassettes to different locations in an efficient way.

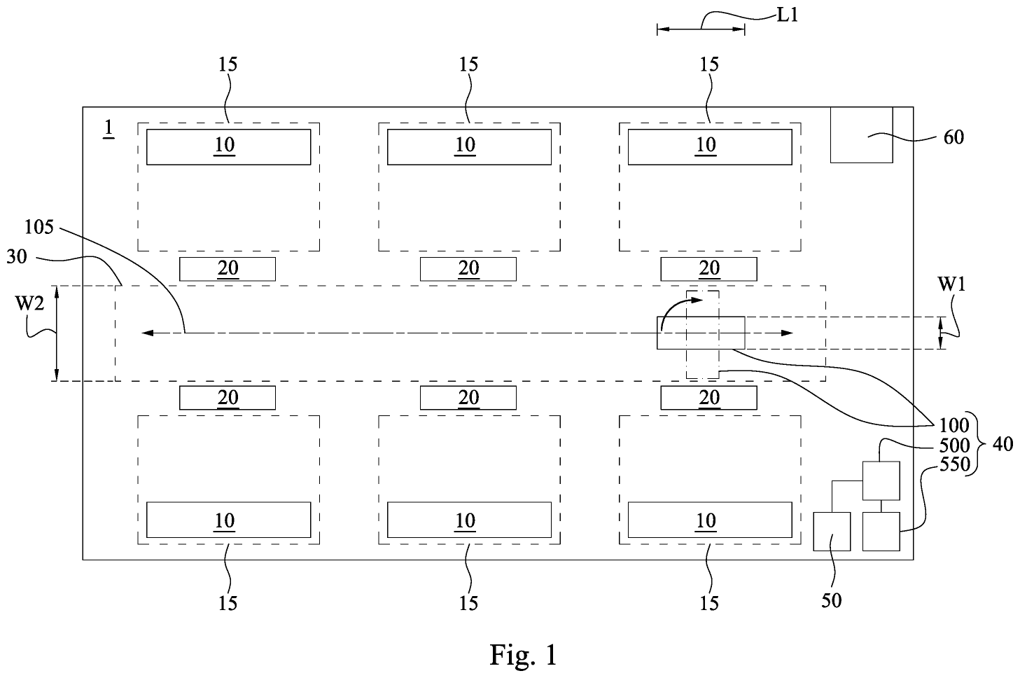

FIG. 1 is an illustrative diagram of a wafer fabrication facility 1 in accordance with some embodiments. The wafer fabrication facility 1 may be a high-level-of-cleanliness cleanroom. In the wafer fabrication facility 1, equipment 10 with similar functions may be clustered in areas 15, which are called process bays or bays. Stockers 20 are respectively located at one end of process bays 15 and an inter-bay aisle 30 is located between the stockers 20. Each of the stockers 20 contains a number of vertically-stacked cells for storing wafer carriers containing semiconductor wafers. A wafer transport system 40 is located in the wafer fabrication facility 1 to transport the wafer carriers. The wafer transport system 40 includes a wafer transport device 100 and a control module 500. During transporting, the wafer transport device 100 runs within the inter-bay aisle 30. In some embodiments, the wafer transport device 100 runs in a loop (e.g., the route 105), picks up wafer carriers from the stockers 20, and drops off wafer carriers at the stockers 120. The control module 500 is communicated with the wafer transport device 100 to control the movement of the wafer transport device 100. It is noted that the number of the wafer transport device 100 is illustrated and is not intended to limit the present disclosure beyond what is explicitly recited in the claims. In some other embodiments, the control module 500 may be communicated with a plurality of the wafer transport devices 100. That is, the control module 500 can control plural wafer transport devices 100. In still some embodiments, the wafer transport system 40 further includes a backup module 550 connected to the control module 500. The backup module 550 is a backup for the control module 500.

Wafers being processed are at the respective equipment 10. When a process is completed on wafers, an operator or a technician unloads a wafer carrier containing the wafers from the equipment 10 of one of the bays 15 and sends the wafer carrier to a nearby first one of the stockers 20. The operator or the technician then picks up the wafer carrier from the first one of stockers 20 and load it to the wafer transport device 100, which transports it to a second one of stockers 20 next to another one of bays 15 where the next process operation is to be performed. The wafer carrier is unloaded from the wafer transport device 100 and then stays in the second one of stockers 20 while waiting for the next processing operation. Then, an operator or a technician from the second one of stockers 20 picks up the wafer carrier and loads the wafer carrier into the corresponding equipment 10. Once all required processing on the wafers are completed, the wafer carrier containing the wafers are transported by wafer transport device 100 to a destination such as a test facility or a packaging facility.

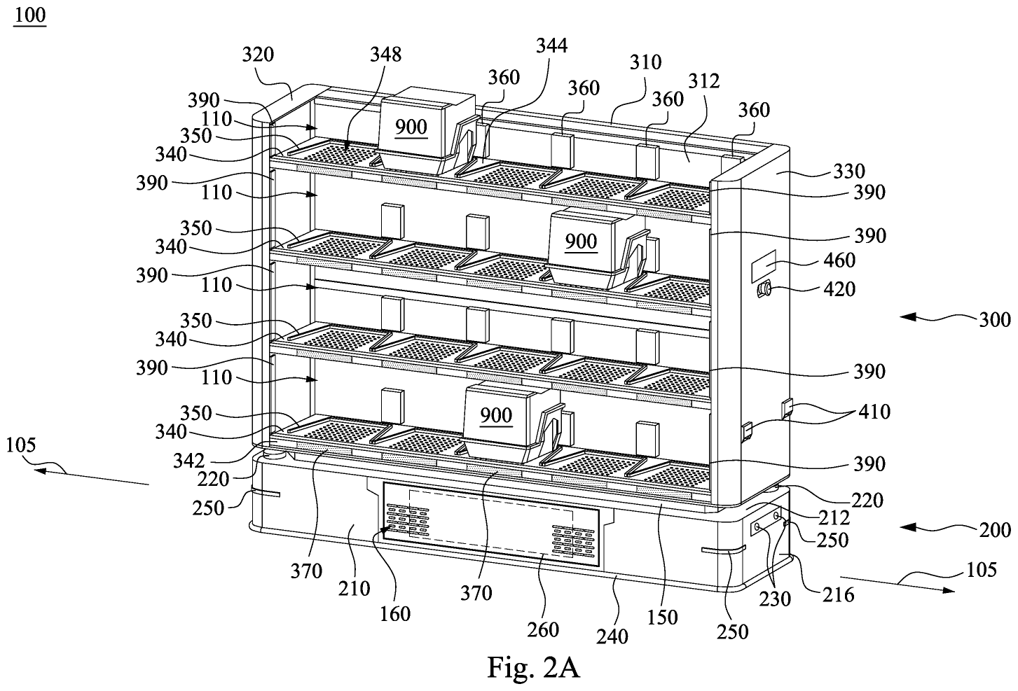

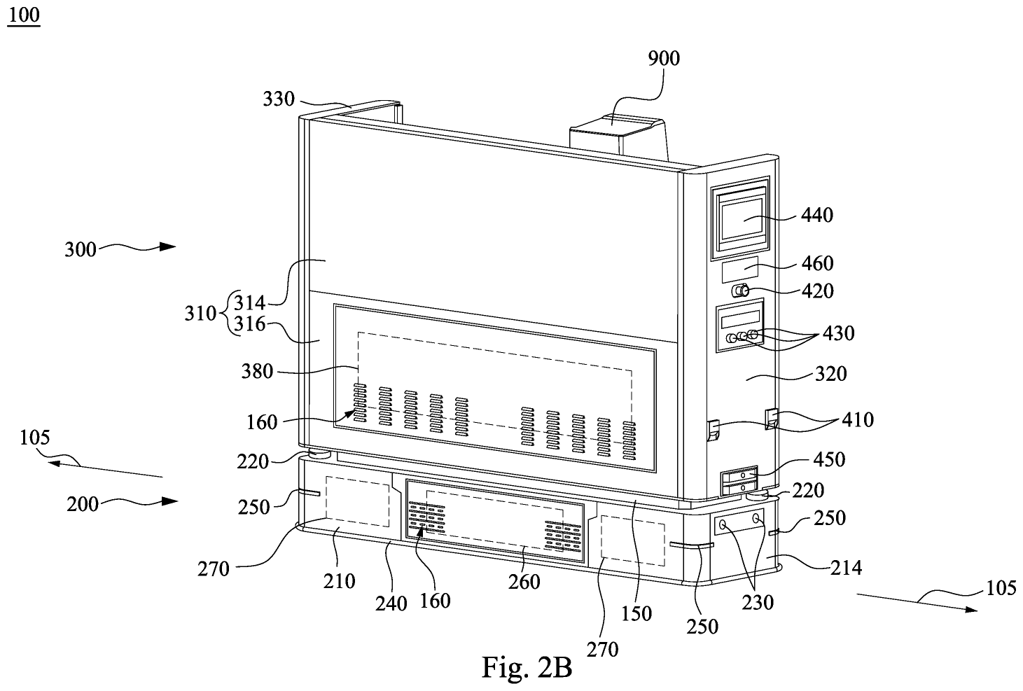

FIGS. 2A and 2B are perspective views of the wafer transport device 100 of FIG. 1 in accordance with some embodiments. The wafer transport device 100 includes a body portion 200 and a rack 300 over the body portion 200. The body portion 200 is configured to support the rack 300 and do the movement of the wafer transport device 100. The rack 300 provides spaces for placing the wafer carriers 900. In some embodiments, the rack 300 is connected to the body portion 200 via a connecting portion 150 of the wafer transport device 100.

The rack 300 includes a rear panel assembly 310, a first side panel 320, a second side panel 330, and a plurality of shelf boards 340. The first side panel 320 and the second side panel 330 are fixed to opposite ends of the rear panel assembly 310, and the shelf boards 340 are secured to at least one of the rear panel assembly 310, the first side panel 320, and the second side panel 330 to fix their positions. As such, accommodating spaces 110 for accommodating the wafer carriers 900 are defined by the rear panel assembly 310, the first side panel 320, the second side panel 330, and the shelf boards 340. In FIG. 2A, four shelf boards 340 are illustrated. However, the number of the boards is not limited to four, and may be as small as 1-3 or more than 4.

Each of the shelf boards 340 can accommodate a plurality of, e.g., five but not limited to, wafer carriers 900. In some embodiments, the rack 300 further includes barriers 350 fixed on the top surfaces 344 of the shelf boards 340. The barriers 350 may be U-shaped in a top view. The barriers 350 define accommodation positions for the wafer carriers 900, such that the wafer carriers 900 are confined to specific positions during movement.

In some embodiments, the rack 300 further includes identification devices 360 fixed on the rear panel assembly 310 and disposed in the accommodating spaces 110. That is, the identification devices 360 can be fixed on an inner surface 312 of the rear panel assembly 310. The identification devices 360 are disposed corresponding to the barriers 350. In other words, the identification devices 360 are disposed at positions where the identification devices 360 are able to scan identifiers (or tags) of the wafer carriers 900 when the wafer carriers 900 are disposed on the shelf boards 340 and confined by the barriers 350. In some embodiments, the identification device 360 is a radio frequency identification (RFID) reader, a barcode scanner, a QR code scanner, or other suitable devices.

In some embodiments, the rack 300 further includes display panels 370 on the front surfaces 342 of the shelf boards 340. Similar to the identification devices 360, the display panels 370 are disposed corresponding to the barriers 350, such that the display panels 370 are able to display data of the corresponding wafer carriers 900. In some embodiments, the display panels 370 are LED panels, liquid crystal panels, or other suitable panels.

The rear panel assembly 310 may include plural components. For example, in FIG. 2B, the rear panel assembly 310 includes a top panel 314 and a bottom panel 316. The top panel 314 may be a metal (e.g., stainless) plate or a plastic plate, and the bottom panel 316 may be a case. In some embodiments, the rack 300 further includes a control unit 380 disposed inside the bottom panel 316. The control unit 380 may be connected to and be communicated with the identification devices 360 and the display panels 370, such that the information of the wafer carriers 900 obtained by the identification devices 360 can be shown on the display panels 370 via the control unit 380. In some embodiments, the control unit 380 includes a power assembly (e.g., battery) to provide power to the components (e.g., the identification devices 360, the display panels 370, and other electronic components described below) of the rack 300.

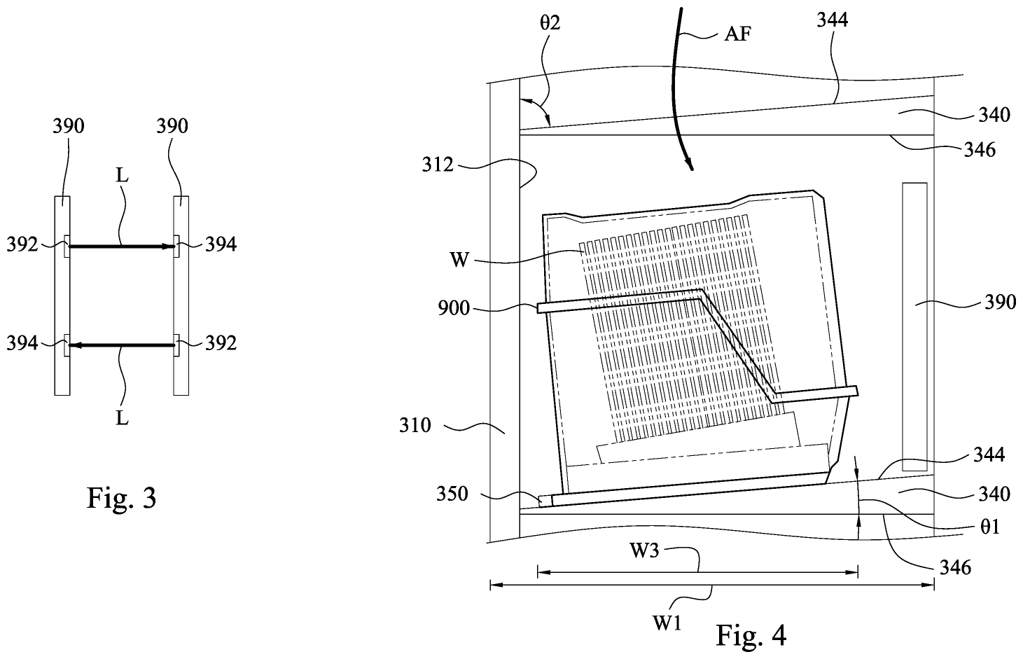

In some embodiments, the rack 300 further includes pairs of optical detectors 390 connected to the control unit 380 and fixed on the first side panel 320 and the second side panel 330. FIG. 3 is a side view of a pair of optical detectors 390 in FIG. 2A. Each pair of optical detectors 390 includes at least one optical source 392 and at least one optical sensor 394. The optical source 392 is aligned with the optical sensor 394, such that a light beam L can be emitted from the optical source 392 to the optical sensor 394. If the wafer carrier 900 is shifted from its initial position and blocks the propagation path of the light beam L, the wafer transport device 100 will deliver a warning or an alarm (audible and/or visible). It is noted that the configuration of the optical sources 392 and the optical sensors 394 in FIG. 3 is illustrative and not intended to limit the present disclosure beyond what is explicitly recited in the claims. In some other embodiments, one of the pair of the optical detectors 390 only includes the optical source(s) 392 and another one of the pair of the optical detectors 390 only includes the optical sensor(s) 394.

FIG. 4 is an enlarged cross-sectional view of the wafer transport device 100 and the wafer carrier 900 in FIG. 2A. In some embodiments, the top surfaces 344 of the shelf boards 340 are inclined to the bottom surfaces 346 of the shelf boards 340. In other words, the shelf boards 340 taper toward the rear panel assembly 310. With such configuration, the wafer carrier 900 is inclined to the rear panel assembly 310, and the configuration prevents the wafer carrier 900 (and wafers W disposed therein) from slipping down the shelf boards 340 during movement. In some embodiments, an angle θ1 formed between the top surface 344 and the bottom surface 346 of the shelf board 340 is in a range from about 5 degrees to about 7 degrees, and an angle θ2 formed between the top surface 344 of the shelf board 340 and the inner surface 312 of the rear panel assembly 310 is in a range from about 83 degrees to about 85 degrees.

Reference is made to FIG. 2A. In some embodiments, the shelf boards 340 have openings 348 therein. As mentioned above, the wafer fabrication facility 1 may be a high-level-of-cleanliness cleanroom, which provides clean airflow AF (see FIG. 4) through the entire room. The airflow AF are configured to remove contamination particles (if exist) in the cleanroom. As shown in FIG. 4, some airflow AF may flow through the wafer carrier 900 to remove possible contamination particles on the wafers W, and the removed contamination particles may flow down to the shelf board 340 and pass through the openings 348 (see FIG. 2A). As such, the contamination particles are not accumulated on the shelf board 340 and contaminate the wafers W again.

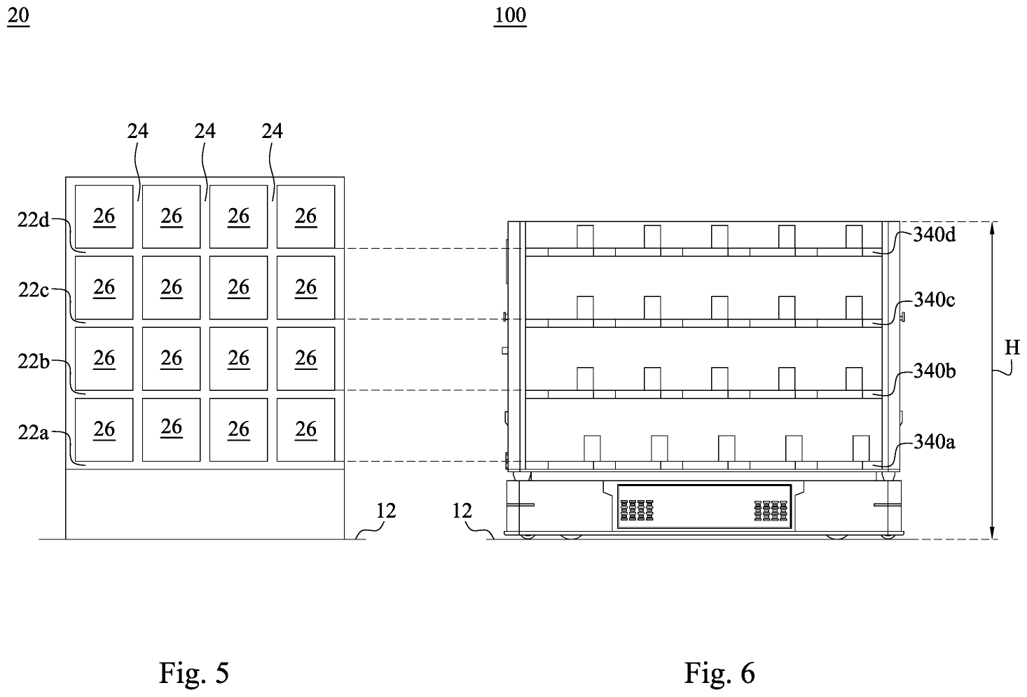

FIG. 5 is a front view of the stocker 20 in FIG. 1 in accordance with some embodiments, and FIG. 6 is a front view of the wafer transport device 100 in FIG. 2A. The heights of the shelf boards (which are labeled to be 340a-340d in FIG. 6 for clarity and ease of explanation) may be determined by the configuration of the stockers 20. As shown in FIG. 5, the stockers 20 have many floors 22a, 22b, 22c, and 22d and partitions 24 together defining individual cells 26. The wafer carriers 900 as shown in FIG. 2A can be disposed in the cells 26, respectively. During the transportation of the wafer carriers 900, an operator or a technician unloads the wafer carrier 900 storing in the cells 26 and transport it to the wafer transport device 100. Alternatively, an operator or a technician unloads the wafer carrier 900 placed in the wafer transport device 100 and transport it to one of the cells 26 of the stocker 20.

In some embodiments, the heights of the shelf boards 340a-340d (e.g., relative to the ground 12 of the wafer fabrication facility 1) are substantially aligned with the heights of the floors 22a-22d. For example, the height of the shelf board 340a is substantially aligned with the height of the floor 22a, the height of the shelf board 340b is substantially aligned with the height of the floor 22b, the height of the shelf board 340c is substantially aligned with the height of the floor 22c, and the height of the shelf board 340d is substantially aligned with the height of the floor 22d. Such configuration is friendly to the operator or the technician since the operator or the technician is able to transport the wafer carriers 900 at the same level and thus reduces the mistakes at transporting. In some embodiments, a height H of the wafer transport device 100 is in a range from 35 cm to about 154 cm.

Reference is made to FIG. 1. A length L1 and/or a width W1 of the wafer transport device 100 may be determined by the size of the inter-bay aisle 30. For example, the width W1 of the wafer transport device 100 may be smaller than a half the width W2 of the inter-bay aisle 30 to allow double-track running and/or keep a walkway in the inter-bay aisle 30. On the other hand, the minimum of the width W1 is determined by the size of the wafer carrier 900. Specifically, as shown in FIG. 4, the width W1 is greater than a width W3 of the wafer carrier 900. In some embodiments, as shown in FIG. 1, the length L1 of the wafer transport device 100 is smaller than the width W2 of the inter-bay aisle 30. As such, the wafer transport device 100 can do spin turns (as illustrated in dash-dotted line in FIG. 1) within the inter-bay aisle 30. In some embodiments, the length L1 of the wafer transport device 100 is in a range from about 50% to about 99% of the width W2 of the inter-bay aisle 30. For example, the length L1 of the wafer transport device 100 is in a range from 40 cm to about 240 cm, and the width W1 of the wafer transport device 100 is in a range from 40 cm to about 80 cm.

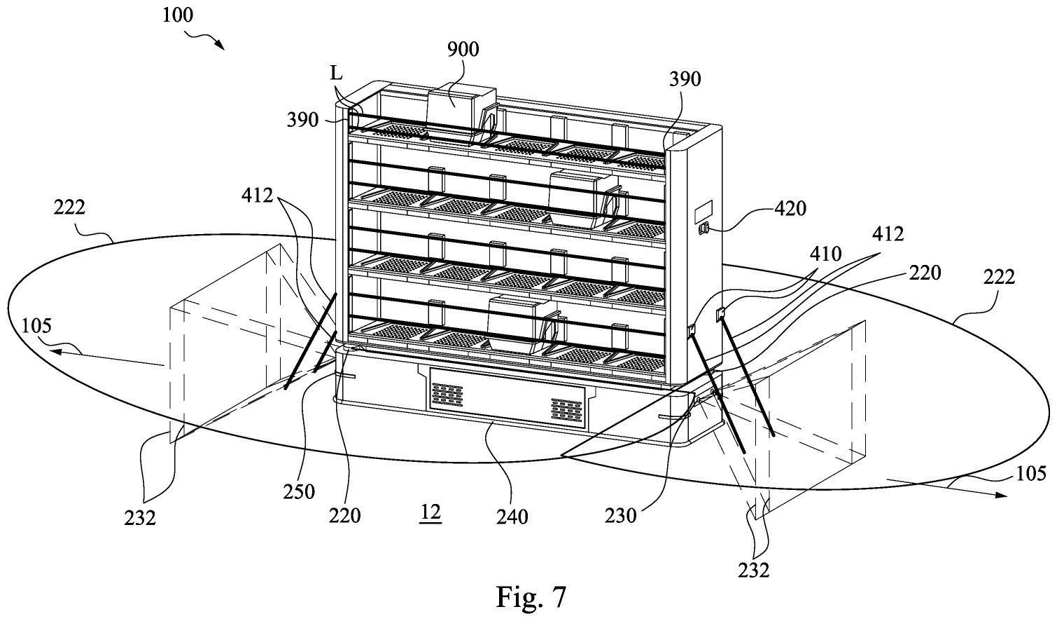

FIG. 7 is a perspective view of the wafer transport device 100 of FIG. 2A during movement. Reference is made to FIGS. 2A, 2B, and 7. During movement, the wafer transport device 100 may move along the route 105. That is, the wafer transport device 100 navigates in the wafer fabrication facility 1. The wafer transport device 100 provides many security mechanisms to make sure the safety of wafers during movement. For example, the optical detectors 390 emit the light beams L during movement. Further, the wafer transport device 100 is able to detect the obstacles in the inter-bay aisle 30. In some embodiments, the rack 300 further includes laser radars 410 fixed on the first side panels 320 and the second side panels 330. Specifically, two of the laser radars 410 are fixed on opposite sides of the first side panels 320 and two of the laser radars 410 are fixed on opposite sides of the second side panels 330. The laser radars 410 are configured to emit laser beams 412 to the ground 12 to detect obstacles in the inter-bay aisle 30. Each of the laser radars 410 further includes a sensor to detect the laser beams 412 reflected from the ground 12. If obstacles are on the ground 12, the laser beams 412 may not be reflected to the sensors of the laser radars 410, such that the wafer transport device 100 will deliver a warning or an alarm (audible and/or visible).

In some embodiments, the body portion 200 includes a case 210 and two wide-angled radars 220 on the top surface 212 of the case 210. The wide-angled radars 220 may be disposed on diagonal corners of the top surface 212 of the case 210. Each of the wide-angled radars 220 has a scan surface 222. If an object touches the scan surface 222, the wafer transport device 100 will deliver a warning or an alarm (audible and/or visible). In some embodiments, the scan surface 222 is a plane with about three-quarter circle. The scan surfaces 222 of the wide-angled radars 220 may overlap with each other to exclude the blind angles.

In some embodiments, the body portion 200 further includes three-dimensional (3D) visual sensors 230 on a first sidewall 214 and a second sidewall 216 of the case 210. Specifically, two of the 3D visual sensors 230 are on opposite sides of the first sidewall 214, and two of the 3D visual sensors 230 are on opposite sides of the second sidewall 216. In other words, the 3D visual sensors 230 are directly below the laser radars 410. Each of the 3D visual sensors 230 has a 3D image region 232 and the 3D visual sensors 230 take images of the 3D image regions 232. The control module 500 is further configured to receive the images obtained by the 3D visual sensors 230 and then recognize the content of the images. If an object touches the 3D image regions 232, the wafer transport device 100 will deliver a warning or an alarm (audible and/or visible). The 3D image regions 232 of the 3D visual sensors 230 fixed on the first sidewall 214 overlap with each other and face forward while the 3D image regions 232 of the 3D visual sensors 230 fixed on the second sidewall 216 overlap with each other and face backward.

In some embodiments, the body portion 200 further includes a bumper strip 240 surrounding the bottom of the case 210. The bumper strip 240 may be made of an elastic material, rubbers, or other suitable materials. Pressure sensors may be embedded in the bumper strip 240, such that the pressure sensors can detect if an object bumps into the bumper strip 240. In some embodiments, the body portion 200 further includes direction indicators 250 on the corners of the case 210. The corresponding direction indicators 250 will be turned on and emit light when the wafer transport device 100 turns. In some embodiments, the direction indicators 250 are able to emit different colors (corresponding to different states, e.g., moving or stop) to remind operators.

In some embodiments, the rack 300 further includes emergency buttons 420 respectively on the first side panel 320 and the second side panel 330. The wafer transport device 100 will immediately stop when the emergency button 420 is pressed. In some embodiments, the rack 300 further includes reset buttons 430 on the first side panel 320. The wafer transport device 100 will be reset when at least one of the reset buttons 432 are pressed or switched. The positions of the emergency buttons 420 and the reset buttons 430 are illustrative and not intended to limit the present disclosure beyond what is explicitly recited in the claims.

In some embodiments, the body portion 200 further includes a control unit 260 in the case 210. The control unit 260 is configured to control the movement and the sensing process of the body portion 200 (or the wafer transporting device 100). In some embodiments, the control unit 260 is connected to the control unit 380, such that the control units 260 and 380 are communicated with each other. The control unit 260 is further connected to motors 270 of the wafer transporting device 100 to control the speed and direction of the wafer transporting device 100. The control unit 260 includes a power assembly (e.g., battery) to provide power to the components (e.g., the wide-angled radars 220, the 3D visual sensors 230, the direction indicators 250, the motors 270, the pressure sensors, and other electronic components described below) of the body portion 200.

In some embodiments, the rack 300 further includes a touch panel 440 fixed on the first side panel 320. The touch panel 440 is connected to the control unit 380 and/or 260 such that the touch panel 440 can be communicated with the control unit 380 and/or 260 (and thus the control module 500). The touch panel 400 is configured to display the information of the wafer carriers 900 and/or the wafer transport device 100. For example, the touch panel 440 may display the battery level of the wafer transport device 100, the speed trend of the wafer transport device 100, the status of the wafer transport device 100, the current and voltage trend of the wafer transport device 100, the product information of each of the wafer carriers 900 loaded on the wafer transport device 100.

Further, in some embodiments, when the wafer carrier 900 is loaded on the stocker 20, the stocker 20 may scan the ID of the wafer carrier 900 and get the information of the wafer carrier 900. The stocker 20 may transfer the information of the wafer carrier 900 to the wafer transport device 100 and show it on the touch panel 440 before the wafer carrier 900 is loaded to the wafer transport device 100. An operator or a technician can read the information shown on the touch panel 440 and then load the corresponding wafer carrier 900 on the wafer transport device 100 when the wafer transport device 100 arrives. In some embodiments, when the touch panel 440 is in an idle state, the touch panel 440 can display different colors and/or icons (corresponding to different states, e.g., moving or stop) to remind operators.

In some embodiments, the rack 300 further includes a charging module 450 fixed on the first side panel 320. As mentioned above, power assemblies are embedded in the case 210 and the bottom panel 316 to provide power to the components of the wafer transport device 100. In some embodiments, the charging module 450 includes a charging board that can be electrically coupled to a charging station 60 (see FIG. 1). It is noted that the positions of the touch panel 440 and the charging module 450 are illustrative and not intended to limit the present disclosure beyond what is explicitly recited in the claims.

The control units 260 and 380 (especially the power assemblies thereof) may generate heat during operation. In some embodiments, the panels near the control units 260 and 380, e.g., the rear panel assembly 310 and the case 210, have vents 160 thereon. With the vents 160, fans, which may occupy extra spaces and waste powers, can be omitted.

The control module 500 in FIG. 1 is communicated with the control units 260 and 380. Further, the control unit(s) 380 and/or 260 is(are) electrically connected to the wide-angled radars 220, the 3D visual sensors 230, the direction indicators 250, the motors 270, the pressure sensors, the identification devices 360, display panels 370, the optical detectors 390, the laser radars 410, the emergency buttons 420, the reset buttons 430, the touch panel 440, and the charging module 450.

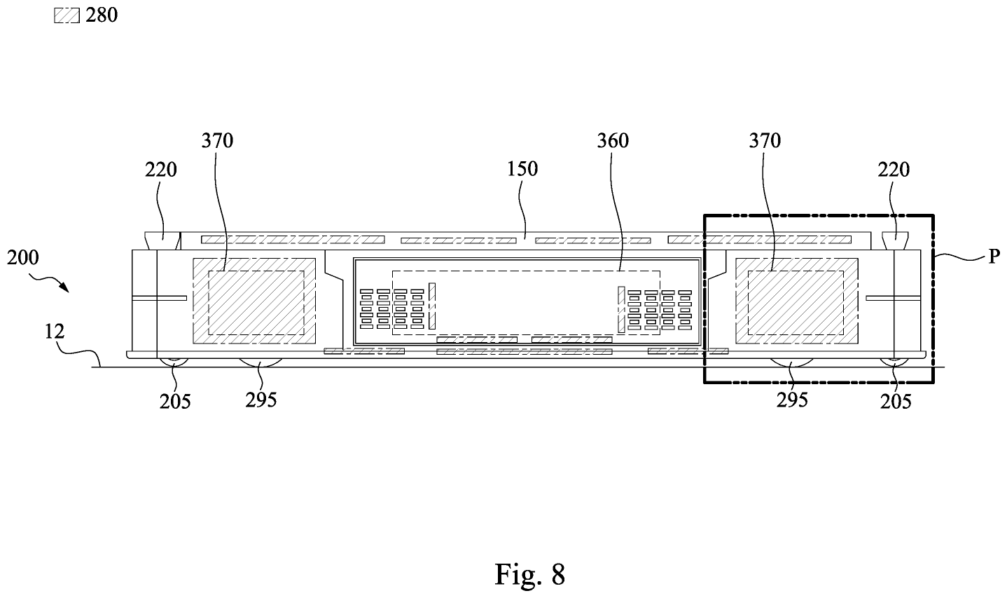

FIG. 8 is a front view of the body portion 200 and the connecting portion 150 in FIG. 2A. In some embodiments, the body portion 200 further includes counterweights 280 embedded in the case 210. The counterweights 280 are configured to gain the total weight of the body portion 200, such that the center of gravity of the wafer transport device 100 is located inside the body portion 200. The counterweights 280 prevent the wafer transport device 100 from flipping over during movement. In some embodiments, some of the counterweights 280 are disposed in the connecting portion 150 of the wafer transport device 100, and/or some of the counterweights 280 are disposed under the bottommost shelf board 340 of the rack 300. The counterweights 280 may have different sizes and/or different weights depending on the sizes and/or locations of available spare spaces in the wafer transport device 100.

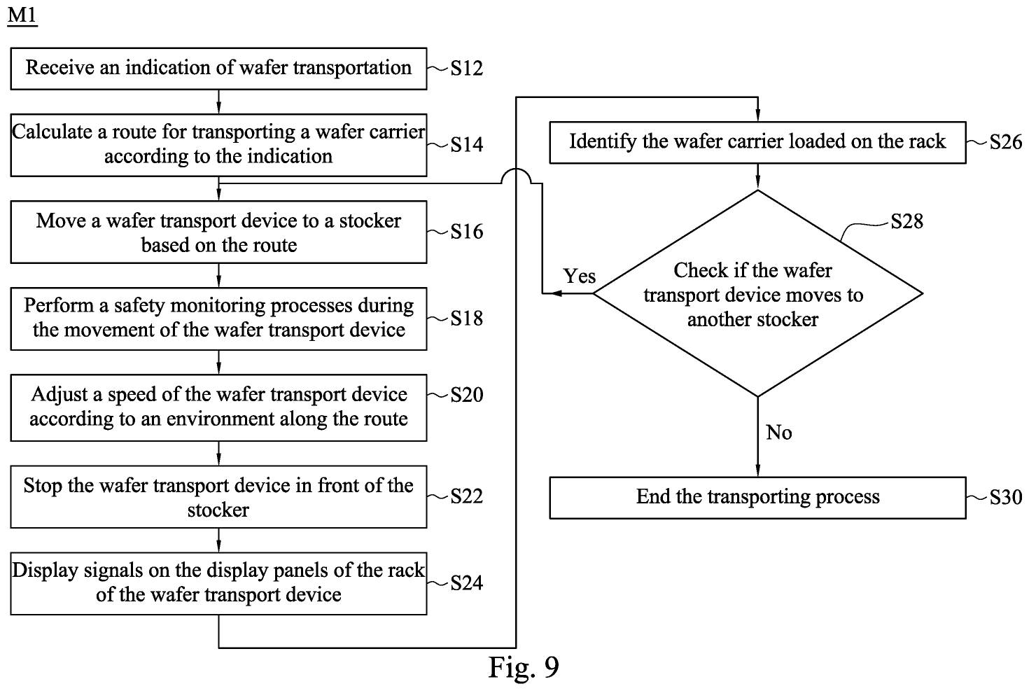

FIG. 9 is a flowchart illustrating a method M1 for transporting wafers (in the wafer carriers 900) in accordance with some embodiments of the present disclosure. Various operations of the method M1 are discussed in association with at least FIGS. 1-8. For illustration purposes, the wafer transport system 40 mentioned above is referenced to collectively describe the details of the method. It is noted that each of the methods presented below is merely an example, and not intended to limit the present disclosure beyond what is explicitly recited in the claims. Additional operations may be provided before, during, and after each of the methods. Some operations described may be replaced, eliminated, or moved around for additional embodiments of the transport methods. Additionally, for clarity and ease of explanation, some elements of the figures have been simplified.

The operation S12 of method M1 includes receiving an indication of wafer transportation. In some embodiments, as shown in FIG. 1, the wafer fabrication facility 1 further includes a main server 50 communicated with the stockers 20 and/or the equipment 10 and is configured to control the operations of the stockers 20 and/or the equipment 10. When the wafer carrier 900 (see FIG. 2A) is transported from the equipment 10 to the corresponding stocker 20, the stocker 20 may read the ID of the wafer carrier 900 and then send an indication of wafer transportation to the main server 50. Alternatively, the equipment 10 may send the indication to the main server 50 when the wafer carrier 900 leaves the equipment 10. Or, an operator or a technician responding for transporting the wafer carrier 900 from the equipment 10 to the corresponding stocker 20 may send the indication to the main server 50. The main server 50 may receive a plurality of indications from different stockers 20 at the same time. After receiving the indication(s), the main server 50 sends the indication(s) to the control module 500 of the wafer transport system 40.

In some embodiments, the main server 50 is configured to manage the tasks of the wafer transporting, the order status and history of the products, the navigation map of the wafer transport devices 100, the status of each of the wafer transport devices 100. The status may include the speeds, positions, battery levels, charging information of the wafer transport devices 100.

The operation S14 of method M1 includes calculating a route for transporting wafers according to the indication. As shown in FIG. 1, the control module 500 is configured to calculate a route 105 for transporting the wafer carriers 900 according to the indication(s). Each of the indications includes an initial station (e.g., a first stocker 20) and a terminal station (e.g., a second stocker 20) of the wafer carrier 900. The route 105 is determined by the initial stations and the terminal stations. That is, the route 105 may include paths for picking up the wafer carriers 900 storing in different stockers 20 and paths for unloading the wafer carriers 900 transported by the wafer transport device 100 to specified stockers 20. In some embodiments, each of the indications further includes an urgent degree of the wafer carrier 900, which may be applied by the main server 50. The route 105 may further be determined by the urgent degrees. For example, the control module 500 generates fast paths and added the fast paths into the route 105 to deal with the urgent lots (the urgent wafer carriers 900). In some embodiments, the route 105 is further determined by the status of the wafer transport device 100. For example, the wafer transport device 100 may be off shift if the battery level thereof is lower than a predetermined level.

The operation S16 of method M1 includes moving the wafer transport device to a stocker based on the route. As shown in FIGS. 1-2B, the control module 500 is communicated with the control unit 260 of the wafer transport device 100 and send the route 105 to the control unit 260. The control unit 260 then controls the motors 270 to navigate or move the wafer transport device 100 to one of the stockers 20 according to the route 105.

The operation S18 of method M1 includes performing safety monitoring processes during the movement of the wafer transport device. For example, as shown above, during movement, the wafer transport device 100 may use the sensors (i.e., the optical detectors 390, the laser radars 410, the wide-angled radars 220, the 3D visual sensors 230, and/or the pressure sensors) to monitor the perimeter of the wafer transport device 100. The wafer transport device 100 may generate an alarm when one or more sensors detect objects. Further, the control unit 260 may control the wafer transport device 100 to do corresponding responses under different alarmed situations. For example, the control unit 260 may deliver an alarm, may stop the wafer transport device 100, may turn a direction of the wafer transport device 100, may slow down the wafer transport device 100, and/or may recalculate the paths of the route 105. Besides the responses made by the control unit 260, the operator or the technician may press the emergency button(s) 420 to stop the wafer transport device 100 under emergency situations. After the object(s) blocking the aisle 30 is(are) excluded or the wafer transport device 100 bypasses the object(s), the wafer transport device 100 then moves along the (new) route 105 again.

The operation S20 of method M1 includes adjusting a speed of the wafer transport device according to an environment along the route. For example, when the wafer transport device 100 moves in a wide area, the control unit 260/380 may accelerate the wafer transport device 100 to speed up the transportation; when the wafer transport device 100 moves in a crowded area, the control unit 260/380 may decelerate the wafer transport device 100 to guarantee the safety of the wafers. In some embodiments, the speed of the wafer transport device 100 may be in a range from about 1 m/s to about 1.2 m/s.

The operation S22 of method M1 includes stopping the wafer transport device in front of the stocker. As shown in FIG. 1, the wafer transport device 100 then moves to a stocker 20 in demands and then is stopped in front of the stocker 20. The wafer transport device 100 may face the stocker 20. Furthermore, the cells 26 of the stocker 20 may be aligned with the accommodation positions (defined by the barriers 350) of the rack 300.

The operation S24 of method M1 includes displaying signals on the display panels of the rack of the wafer transport device. Specifically, in some embodiments, the control module 500 may further assign accommodation positions on the shelf boards 340 for the wafer carriers 900 that are supposed to be loaded on the wafer transport device 100. For example, the control module 500 may consider the level (height) of the wafer carriers 900 storing in the stockers 20 to assign the accommodation positions. Therefore, the cell 26 storing the wafer carrier 900 and the corresponding accommodation position may be at the same level as shown in FIGS. 5 and 6. When the wafer transport device 100 is stopped in front of the stocker 20, the control module 500 controls the display panel 370 of the specified accommodation position to display a signal (e.g., colored light, pulsed light, an ID pattern of the corresponding wafer carrier 900, or other suitable signals).

In still some embodiments, the control module 500 may further assign the location of the cells 26 for the wafer carriers 900 disposed on the rack 300 of the wafer transport device 100 and supposed to be unloaded to the stocker 20. For example, the control module 500 may consider the level (height) of the wafer carriers 900 disposed on the shelf boards 340 to assign the cells 26. Therefore, the cell 26 storing the wafer carrier 900 and the corresponding accommodation position may be at the same level as shown in FIGS. 5 and 6. When the wafer transport device 100 is stopped in front of the stocker 20, the control module 500 controls the display panel 370 of the specified wafer carrier 900 to display a signal (e.g., colored light, pulsed light, an ID pattern of the corresponding cell 26, or other suitable signals).

Subsequently, the operator or the technician may manually pick up the wafer carrier 900 in the cell 26 of the stocker 20 and load the wafer carrier 900 to the specified accommodation position having the highlight display panel 370 and/or unload the wafer carrier 900 on the wafer transport device 100 with another highlight display panel 370 to a specified cell 26 of the stocker 20. In some other embodiments, a transport robot is configured to transport the wafer carrier 900 between the stocker 20 and the wafer transport device 100. In this case, the operation S24 can be omitted.

In some embodiments, during the loading/unloading of the wafer carriers 900, the optical detectors 390 are still operating. Therefore, when the wafer carriers 900 touch the light beams L, the optical detectors 390 will send a signal to the control module 500. As the control module 500 receives the signal, the control module 500 will deliver an order to the control unit 260, which then controls the motors 270 to stay stopped. As such, the wafer transport system 40 guarantees that the wafer transport device 100 stay stopped when the wafer carriers 900 are loading/unloading.

The operation S26 of method M1 includes identifying the wafer carrier loaded on the rack. As shown in FIG. 2A, when the wafer carrier 900 is loaded on the shelf board 340 and is confined to the specified accommodation position defined by the barrier 350, the corresponding identification device 360 will scan the ID of the wafer carrier 900. The identification device 360 then send the ID to the control unit 380 and/or 260, and the control unit 380 and/or 260 confirms the placement of the wafer carrier 900. The control unit 380 and/or 260 may further check if the wafer carrier 900 is loaded in the right accommodation position. If not, the control unit 380 and/or 260 can deliver a warning or an alarm (audible and/or visible) and may display the alarm on the corresponding display panel 370. As such, the operator or the technician is able to correct the loading position of the wafer carrier 900. On the other hand, for the wafer carriers 900 unloaded to the stocker 20, the corresponding identification device 360 also performs a scan process to confirm if the wafer carrier 900 is absent. Also, the control unit 380 and/or 260 can deliver a warning or an alarm (audible and/or visible) and may display the alarm on the corresponding display panel 370 if the corresponding identification device 360 detects the wafer carrier 900.

The operation S28 of method M1 includes checking if the wafer transport device moves to another stocker. As shown in FIG. 1, after the wafer transport device 100 confirms the loading/unloading processes are completed for the first stocker 20, the control module 500 then proceeds with the route 105. The method M1 then goes back to the operation S16 if the wafer transport device is scheduled to move to another stocker. In some other embodiments, the method M1 goes to the operation S30 including ending the transporting process if the wafer transport device is not scheduled to move to another stocker. There are some scenarios that the wafer transport device does not move to another stocker. For example (but not limited to), the wafer transport device 100 has low battery, the wafer transport device 100 is shut down, the wafer transport device 100 is off shift, the wafer transport device 100 is in maintenance, and/or emergency occurs in the wafer fabrication facility 1.

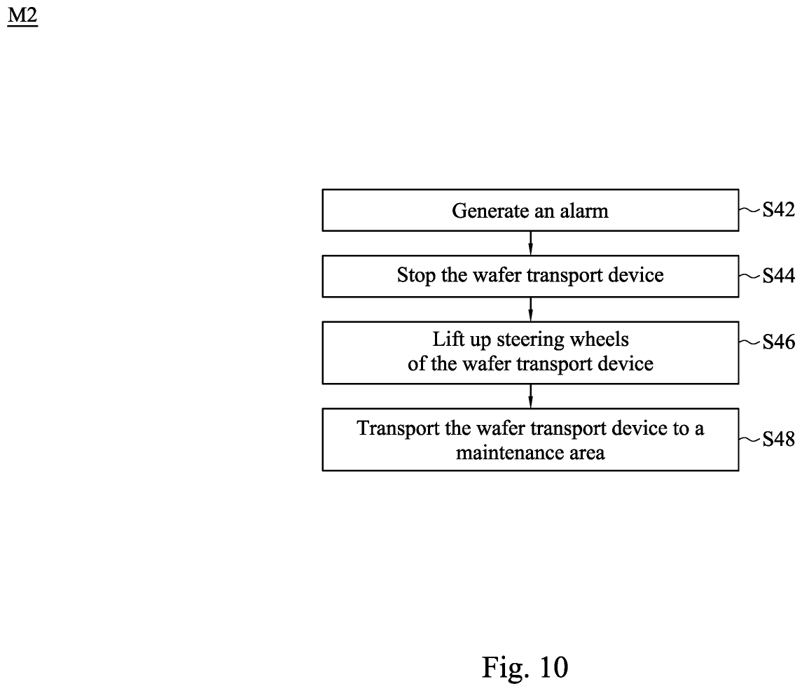

FIG. 10 is a flowchart illustrating a method M2 for maintaining the wafer transport device 100 in accordance with some embodiments of the present disclosure. Various operations of the method M2 are discussed in association with at least FIGS. 1-8. For illustration purposes, the wafer transport system 40 mentioned above is referenced to collectively describe the details of the method. It is noted that each of the methods presented below is merely an example, and not intended to limit the present disclosure beyond what is explicitly recited in the claims. Additional operations may be provided before, during, and after each of the methods. Some operations described may be replaced, eliminated, or moved around for additional embodiments of the transport methods. Additionally, for clarity and ease of explanation, some elements of the figures have been simplified.

The operation S42 of method M2 includes generating an alarm. For example, as shown in operation S18 and FIG. 7, the wafer transport device 100 may generate an alarm if at least one of the sensors detects object. The alarm may be audible (sound) and/or visible (optical). In some other embodiments, the wafer transport device 100 may generate an alarm when the battery level of the wafer transport device 100 is low.

The operation S44 of method M2 includes stopping the wafer transport device. In some embodiments, as shown in FIG. 7, an operator or a technician can manually press the emergency button 420 when he or she notes the alarm. Once the emergency button 420 is pressed, the wafer transport device 100 is stopped. In some other embodiments, the control units 260/380 may control the motors 270 to automatically stop the wafer transport device 100. Prior to stop the wafer transport device 100, the control module 500 may further recalculate the route 105 to park the wafer transport device 100 in a parking area of the wafer fabrication facility 1. In some embodiments, the operator or the technician may then press the reset buttons 430 to restart the control units 260/380 of the wafer transport device 100. However, in some embodiments, the wafer transport device 100 is out of function, and may be manually moved to a maintenance area of the wafer fabrication facility 1.

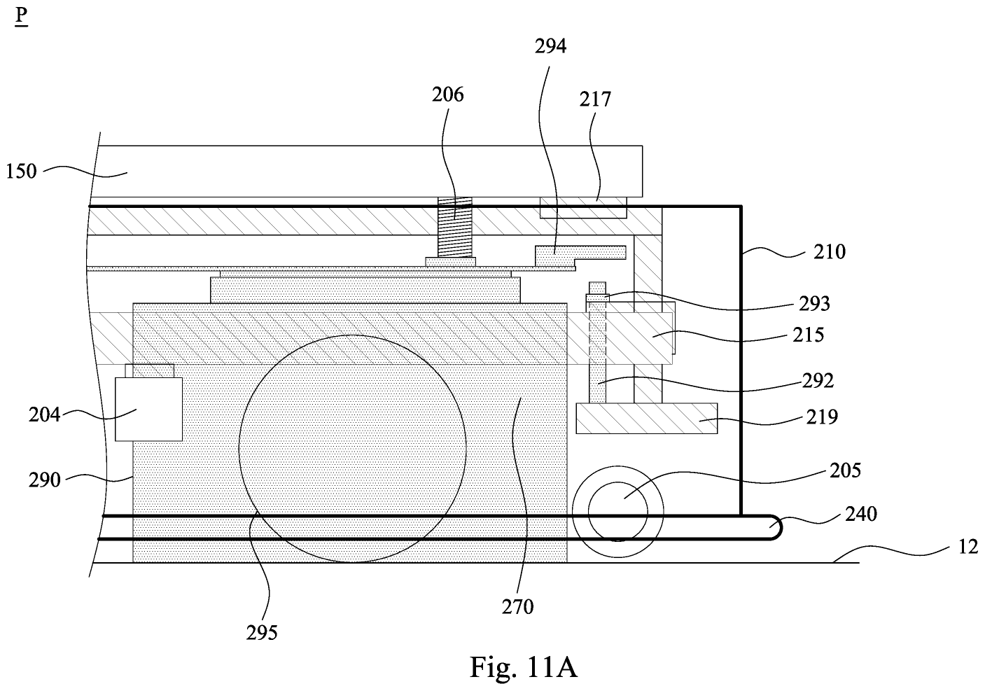

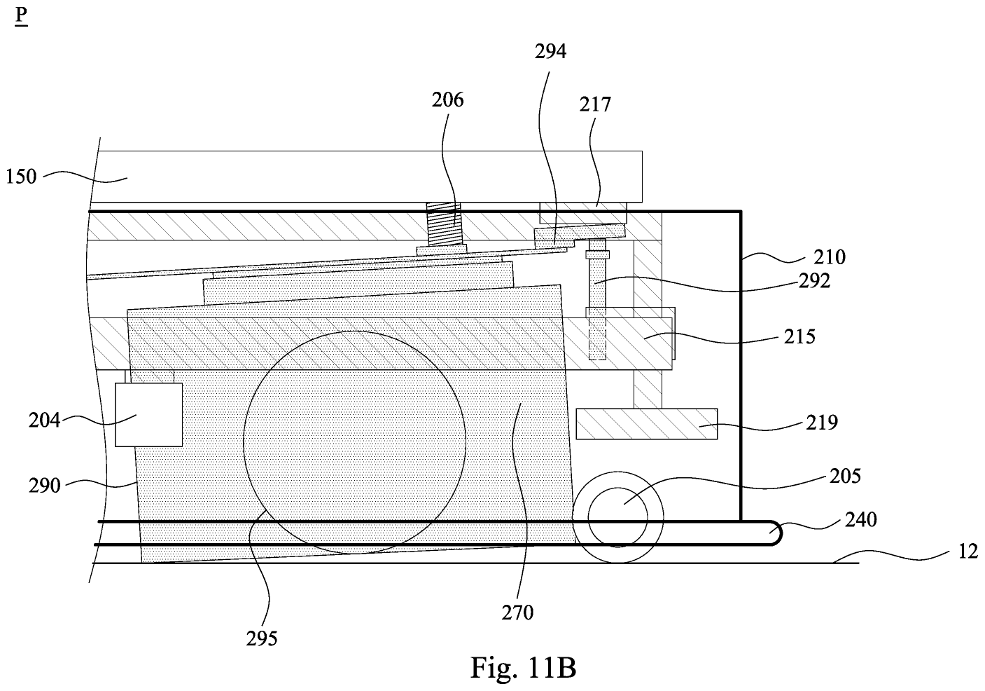

The operation S46 of method M2 includes lifting up steering wheels of the wafer transport device. FIG. 11A is an enlarged view of area P in FIG. 8, and FIG. 11A also shows some frames 215 inside the case 210 of the body portion 200. Reference is made to FIGS. 8 and 11A. Specifically, the body portion 200 further includes steering assemblies 290 inside the case 210, and each of the steering assemblies 290 includes a steering wheel 295 and the motor 270. The motors 270 are respectively connected to the steering wheels 295 and configured to drive the steering wheels 295. The body portion 200 further includes auxiliary wheels 205 attached to the case 210. As shown in FIG. 11A, when the wafer transport device 100 is working, the steering wheels 295 touch the ground 12 while the auxiliary wheels 205 are suspended above the ground 12.

FIG. 11B is an enlarged view of area P in FIG. 8 when the steering wheel 295 is lifted up. Reference is made to FIGS. 11A and 11B. The steering assembly 290 further includes a pole screw 292 passing through the frame 215 of the case 210 and a plate 294 directly above the pole screw 292. The steering assembly 290 is connected to the frame 215 of the case by a hinge 204. During the lifting of the steering assembly 290, an operator or a technician may use a wrench to screw the hex head 293 of the pole screw 292, such that the pole screw 292 moves upwards and then touches the plate 294. The pole screw 292 then pushes the plate 294 upwards to an upper limit block 217 of the frame 215. When the plate 294 is pushed upward, the steering assembly 290 (and thus the steering wheel 295) is rotated with respect to the hinge 204 and thus the steering wheel 295 is lifted from the ground 12. Hence, the auxiliary wheels 205 touch the ground 12 instead.

In some embodiments, the body portion 200 further includes springs 206 respectively above the steering assemblies 290. That is, each of the springs 206 is between the steering assembly 290 and the connecting portion 150. When the steering assembly 290 is lifted, the steering assembly 290 pushes the spring 206 and thus the spring 206 is compressed as shown in FIG. 11B.

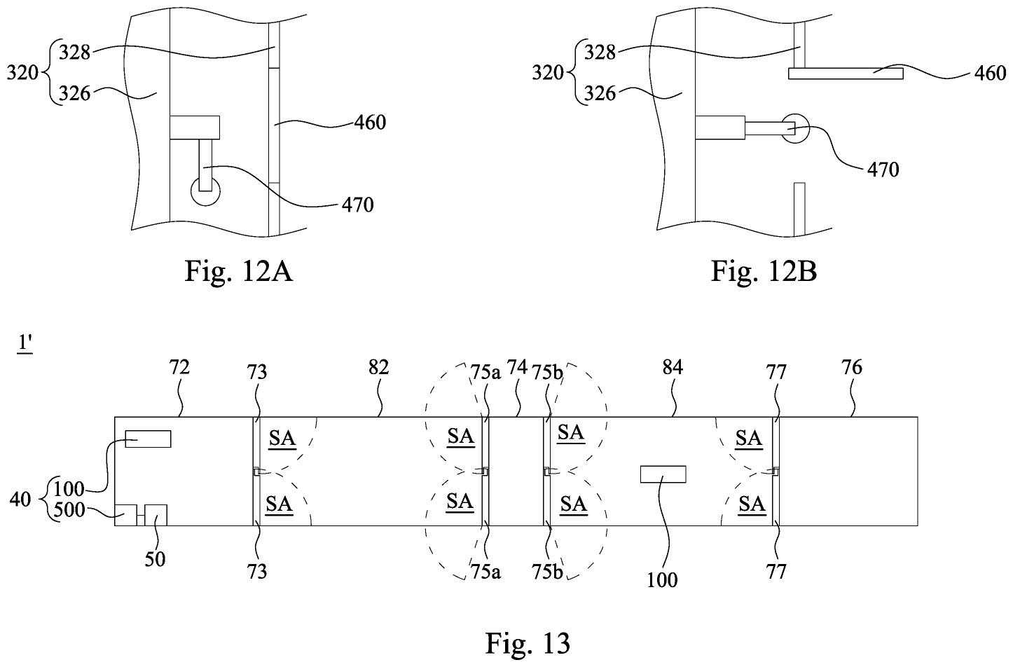

The operation S48 of method M2 includes transporting the wafer transport device to a maintenance area. As shown in FIGS. 2A and 2B, the rack 300 further includes lids 460 on the first side panel 320 and the second side panel 330, respectively. FIGS. 12A and 12B are enlarged side views of the first side panel 320 (or the second side panel 330) in accordance with some embodiments. Take the first side panel 320 as an example, the first side panel 320 includes a frame structure 326 and a cover 328 covering the frame structure 326. The lid 460 is disposed on the cover 328. The rack 300 further includes handles 470 on the first side panel 320 and the second side panel 330, respectively. For example, as shown in FIG. 12A, the handle 470 is fixed on the frame structure 326. Normally, the lids 460 cover the handles 470, and the handles 470 are folded as shown in FIG. 12A. When the lids 460 are uncovered as shown in FIG. 12B, the handles 470 are exposed from the covers 328. As such, with the auxiliary wheels 205 touch the ground 12, operators or technicians may pull and hold the handles 470 and then push the wafer transport device 100 to the maintenance area of the wafer fabrication facility 1.

In some embodiments, after the maintenance of the wafer fabrication facility 1, the steering wheels 295 may be put down to the ground 12 again. As shown in FIGS. 11A and 11B, an operator or a technician may use a wrench to screw the hex head 293 of the pole screw 292, such that the pole screw 292 moves downwards and then touches the lower limit block 219 of the frame 215. The plate 294 is then released, and the spring 206 is relaxed to its normal length. The spring 206 thus generates a pushing force to push the steering assembly 290 (and thus the steering wheel 295) downwards and thus the steering wheel 295 touches the ground 12. In the meantime, the auxiliary wheels 205 are suspended above the ground 12 again as shown in FIG. 11A.

In some embodiments, the wafer transport device 100 may move within different areas/rooms/phases of the semiconductor fabrication facility. FIG. 13 is an illustrative diagram of a wafer fabrication facility 1′ in accordance with some embodiments. In some embodiments, the wafer fabrication facility 1′ includes rooms (or phases) 72, 74, and 76 and passageways 82 and 84 connecting the rooms 72, 74, and 76. For example, the passageway 82 interconnects the rooms 72 and 74, and the passageway 84 interconnects the rooms 74 and 76. One or more wafer transport device(s) 100 may move within the rooms 72, 74, and 76 and the passageways 82 and 84.

The wafer fabrication facility 1′ further includes fire exit doors 73, 75a, 75b, and 77 at the exits of the rooms 72, 74, and 76. When a fire alarm is triggered, the fire exit doors 73, 75a, 75b, and/or 77 are opened according to the fire location. For example, if a fire occurs in the room 72, the fire exit doors 73 are opened, if a fire occurs in the room 74, the fire exit doors 75a and 75b are opened, and if a fire occurs in the room 76, the fire exit doors 77 are opened, such that the operators or the technician can escape from the rooms 72, 74, and/or 76.

In some embodiments, the wafer transport system 40 is communicated with a fire system, which may be in the main server 50 of the wafer fabrication facility 1′. As such, when the fire occurs, the control module 500 will determine the movements of each of the wafer transport devices 100 according to their present locations. The wafer transport device(s) 100 can move to spare locations that are not the escape passages or the door swing areas SA of the corresponding fire exit doors 73, 75a, 75b, and 77.

For example, when the fire occurs, if the wafer transport device 100 is at or near one of the door swing areas SA of the corresponding fire exit doors 73, 75a, 75b, and 77 that are supposed to be opened, the control module 500 will recalculate the route 105 for the wafer transport device 100 immediately to move the wafer transport device 100 out of the door swing area SA. When the fire occurs, if the wafer transport device 100 is already at the spare location, the wafer transport device 100 will immediately stop. However, if the wafer transport device 100 is in the fire room, the control module 500 will turn off the safety monitoring process and recalculate the route 105 for the wafer transport device 100 immediately to move the wafer transport device 100 out of the fire room and then stop the wafer transport device 100 at a nearby spare location out of the fire area.

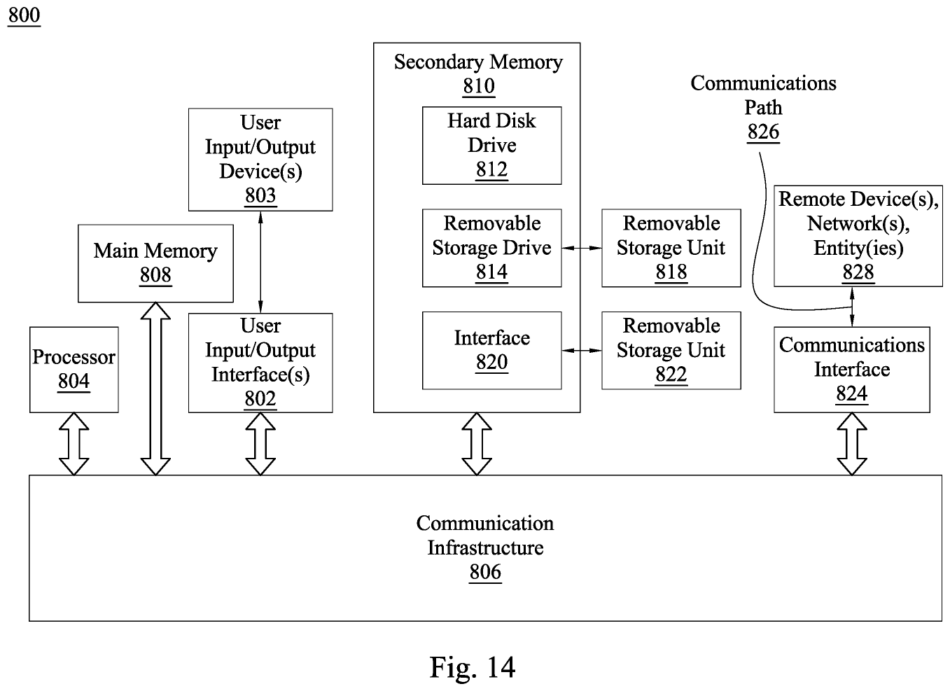

FIG. 14 a schematic diagram illustrating a computer system 800 in accordance with some embodiments of the present disclosure. In some embodiments, at least one of the control module 500, the main server 50, and the control unit 260/380 may be also known as a computer system 800. As shown in FIG. 14, an illustration of an exemplary computer system 800 in which various embodiments of the present disclosure can be implemented, according to some embodiments. The computer system 800 may be used to control various components in the wafer transport system 40 or the wafer fabrication facility 1, 1′. The computer system 800 may be any well-known computer capable of performing functions and operations described in the present disclosure. For example, and without limitation, the computer system 800 may be capable of processing and transmitting signals. The computer system 800 may be used, for example, to execute one or more functions of the wafer transport system 40 or the wafer fabrication facility 1, 1′, which describes example operations of communications amongst different components therein.

The computer system 800 may include one or more processors (also called central processing units, or CPUs), such as a processor 804. The processor 804 is connected to a communication infrastructure or bus 806. The computer system 800 also includes input/output device(s) 803, such as monitors, keyboards, and pointing devices, that may communicate with communication infrastructure or bus 806 through input/output interface(s) 802. The computer system 800 may receive instructions to implement functions and operations described herein, e.g., functions of the wafer transport system 40 or the wafer fabrication facility 1, 1′ and methods M1 and M2, via the input/output device(s) 803. The computer system 800 also includes a main or primary memory 808, such as random access memory (RAM). The main memory 808 may include one or more levels of cache. The main memory 808 has stored therein control logic (e.g., computer software) and/or data. In some embodiments, the control logic (e.g., computer software) and/or data may include one or more of the functions described with respect to the wafer transport system 40 or the wafer fabrication facility 1, 1′.

The computer system 800 may also include one or more secondary storage devices or memory 810. The secondary memory 810 may include, for example, a hard disk drive 812 and/or a removable storage device or drive 814. Removable storage drive 814 can be a floppy disk drive, a magnetic tape drive, a compact disk drive, an optical storage device, tape backup device, and/or any other storage device/drive.

The removable storage drive 814 may interact with a removable storage unit 818. The removable storage unit 818 includes a computer usable or readable storage device having stored thereon computer software (control logic) and/or data. The removable storage unit 818 may be a floppy disk, magnetic tape, compact disk, DVD, optical storage disk, and/any other computer data storage device. The removable storage drive 814 reads from and/or writes to removable storage unit 818 in a well-known manner.

In some embodiments, the secondary memory 810 may include other means, instrumentalities or other approaches for allowing computer programs and/or other instructions and/or data to be accessed by the computer system 800. Such means, instrumentalities or other approaches can include, for example, a removable storage unit 822 and an interface 820. Examples of the removable storage unit 822 and the interface 820 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, the secondary memory 810, the removable storage unit 818, and/or the removable storage unit 822 may include one or more of the functions described with respect to the wafer transport system 40 or the wafer fabrication facility 1, 1′.

The computer system 800 may further include a communication or network interface 824. The communication interface 824 enables the computer system 800 to communicate and interact with any combination of remote devices, remote networks, remote entities, etc. (individually and collectively referenced by reference number 828). For example, the communication interface 824 may allow the computer system 800 to communicate with the remote devices 828 over the communications path 826, which may be wired and/or wireless, and which may include any combination of LANs, WANs, the Internet, etc. Control logic and/or data may be transmitted to and from the computer system 800 via the communication path 826.

The functions and/or operations in the preceding embodiments may be implemented in a wide variety of configurations and architectures. Therefore, some or all of the operations in the preceding embodiments, e.g., functions of the wafer transport system 40 or the wafer fabrication facility 1, 1′ and methods M1 and M2, may be performed in hardware, in software or both. In some embodiments, a tangible apparatus or article of manufacture including a tangible computer useable or readable medium having control logic (software) stored thereon is also referred to herein as a computer program product or program storage device. This includes, but is not limited to, the computer system 800, the main memory 808, the secondary memory 810, and the removable storage units 818 and 822, as well as tangible articles of manufacture embodying any combination of the foregoing. Such control logic, when executed by one or more data processing devices (such as the computer system 800), causes such data processing devices to operate as described in the present disclosure. In some embodiments, the computer system 800 includes hardware/equipment for the manufacturing of photomasks and circuit fabrication. For example, the hardware/equipment may be connected to or be part of the element 828 (remote device(s), network(s), entity(ies)) of the computer system 800.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the wafer transport system can be used in the high-level-of-cleanliness cleanrooms to save manpower, which may be reduced more than 30%. Moreover, the wafer transport system speeds up the transportation time and thus is effective for wafer transporting. Further, the wafer transport system is able to calculate the transportation route in real time, and the route can be modified/adjusted/recalculated in demands. In addition, the wafer transport system can be communicated with a fire system such that the wafer transport devices can move to safe area as soon as possible when a fire alarm is triggered.

According to some embodiments, a method includes receiving, by a control module of a wafer transport system, an indication of wafer transporting; calculating, by the control module, a route for transporting a first wafer carrier according to the indication; moving, by a control unit of a wafer transport device of the wafer transport system, the wafer transport device to a first stocker storing the first wafer carrier along the route; performing, by the control unit, a safety monitoring process during a movement of the wafer transport device; stopping, by the control unit, the wafer transport device in front of the first stocker; and identifying, by an identification device of the wafer transport device, the first wafer carrier loaded on a rack of the wafer transport device.

According to some embodiments, a method includes receiving, by a control module of a wafer transport system, a first indication corresponding to a first wafer carrier and a second indication corresponding to a second wafer carrier, wherein the first wafer carrier is stored in a stocker and the second wafer carrier is placed in a wafer transport device of the wafer transport system; calculating, by the control module, a route of the wafer transport device according to the first indication and the second indication; moving, by a control unit of the wafer transport device, the wafer transport device to the stocker along the route; performing, by a first identification device of the wafer transport device, a first scan process to confirm if the first wafer carrier is loaded on the wafer transport device; and performing, by a second identification device of the wafer transport device, a second scan process to confirm if the second wafer carrier is unloaded from the wafer transport device.

According to some embodiments, a wafer transport system includes a wafer transport device and a control module. The wafer transport device includes a body portion and a rack supported by the body portion. The body portion includes a case and a steering assembly inside the case. The rack includes a rear panel assembly, a first side panel, a second side panel, and a plurality of shelf boards. The first side panel and the second side panel are fixed on opposite ends of the rear panel assembly. The plurality of shelf boards are secured to at least one of the rear panel assembly, the first side panel, and the second side panel to define accommodating spaces for accommodating a wafer carrier. The control module is communicated with the wafer transport device, is configured to determine a route for moving the wafer transport device, and is configured to control the steering assembly to move the wafer transport device along the route.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
receiving, by a control module of a wafer transport system, an indication of wafer transporting;
calculating, by the control module, a route for transporting a first wafer carrier according to the indication;
moving, by a control unit of a wafer transport device of the wafer transport system, the wafer transport device to a first stocker storing the first wafer carrier along the route;
performing, by the control unit, a safety monitoring process during a movement of the wafer transport device;
stopping, by the control unit, the wafer transport device in front of the first stocker; and
identifying, by an identification device of the wafer transport device, the first wafer carrier loaded on a rack of the wafer transport device.

2. The method of claim 1, further comprising:
after identifying the first wafer carrier loaded on the rack of the wafer transport device, moving the wafer transport device to a second stocker along the route.

3. The method of claim 2, further comprising:
after moving the wafer transport device to the second stocker, performing a scan process, by the identification device, to confirm if the first wafer carrier is absent.

4. The method of claim 2, further comprising:
displaying a signal on a display panel of the rack of the wafer transport device corresponding to the first wafer carrier when the wafer transport device is stopped in front of the second stocker.

5. The method of claim 1, further comprising:
displaying a signal on a display panel of the rack of the wafer transport device corresponding to the first wafer carrier when the wafer transport device is stopped in front of the first stocker.

6. The method of claim 1, further comprising:
adjusting, by the control unit, a speed of the wafer transport device according to an environment along the route.

7. The method of claim 1, wherein the route is calculated based on an urgent degree of the first wafer carrier.

8. A method comprising:
receiving, by a control module of a wafer transport system, a first indication corresponding to a first wafer carrier and a second indication corresponding to a second wafer carrier, wherein the first wafer carrier is stored in a stocker and the second wafer carrier is placed in a wafer transport device of the wafer transport system;
calculating, by the control module, a route of the wafer transport device according to the first indication and the second indication;
moving, by a control unit of the wafer transport device, the wafer transport device to the stocker along the route;
performing, by a first identification device of the wafer transport device, a first scan process to confirm if the first wafer carrier is loaded on the wafer transport device; and
performing, by a second identification device of the wafer transport device, a second scan process to confirm if the second wafer carrier is unloaded from the wafer transport device.

9. The method of claim 8, further comprising:
after performing the first scan process and the second scan process, moving, by the control unit, the wafer transport device to another stocker.

10. The method of claim 8, further comprising:
emitting, by an optical detector of the wafer transport device, a light beam on a rack of the wafer transport device to detect if the second wafer carrier is moving when moving the wafer transport device to the stocker.

11. The method of claim 8, further comprising:
detecting, by a sensor of the wafer transport device, objects around a perimeter of the wafer transport device when moving the wafer transport device to the stocker.

12. The method of claim 8, further comprising:
recalculating, by the control module, the route of the wafer transport device when a fire alarm is received by the control module.

13. The method of claim 8, further comprising:
displaying information of the first wafer carrier on a touch panel of the wafer transport device prior to moving the wafer transport device to the stocker.

14. The method of claim 8, further comprising:
assigning, by the control module, an accommodation position in the wafer transport device for the first wafer carrier according to a level of the stocker for storing the first wafer carrier.

15. A wafer transport system comprising:
a wafer transport device comprising:
a body portion comprising:
a case; and
a steering assembly inside the case; and
a rack supported by the body portion and comprising:
a rear panel assembly;
a first side panel and a second side panel fixed on opposite ends of the rear panel assembly; and
a plurality of shelf boards secured to at least one of the rear panel assembly, the first side panel, and the second side panel to define accommodating spaces for accommodating a wafer carrier; and
a control module communicated with the wafer transport device, wherein the control module:
is configured to determine a route for moving the wafer transport device; and
is configured to control the steering assembly to move the wafer transport device along the route.

16. The wafer transport system of claim 15, wherein the wafer transport device further comprises a wide-angled radar on a top surface of the case.

17. The wafer transport system of claim 15, wherein the wafer transport device further comprises a bumper strip surrounding a bottom of the case.

18. The wafer transport system of claim 15, wherein an angle is defined between a top surface of at least one of the shelf boards and an inner surface of the rear panel assembly, and the angle is in a range from about 83 degrees to about 85 degrees.

19. The wafer transport system of claim 15, wherein the shelf boards have openings.

20. The wafer transport system of claim 15, wherein the first side panel comprises:
a frame structure;
a cover covering the frame structure, wherein the rack further comprises:
a lid fixed on the cover; and
a handle fixed on the frame structure and covered by the lid.
